(19) United States
(12) Patent Application Publication
(10) Pub. No.: US 2025/0221091 A1
(43) Pub. Date: Jul. 3, 2025

(54) PHOTONICS DEVICE WITH BACKSIDE TRANSMISSIVE REGION

(71) Applicant: Taiwan Semiconductor Manufacturing Company, Ltd., Hsinchu (TW)

(72) Inventors: Shih-Yu LIAO, Hsinchu City (TW); Tao-Cheng LIU, Hsinchu City (TW)

(21) Appl. No.: 18/398,937

(22) Filed: Dec. 28, 2023

(51) Int. Cl. H01L 31/0232; H01L 31/0216; H01L 31/18

(52) U.S. Cl. CPC H10F 77/413; H10F 71/00; H10F 77/306

(57) ABSTRACT

Some implementations described herein provide techniques and apparatuses provide a semiconductor device including a photonics device having a backside transmissive region and methods of manufacturing. The semiconductor device includes a first semiconductor device stacked over a second semiconductor device, where the first semiconductor device includes a photodiode structure and the second semiconductor device includes the backside transmissive region. The backside transmissive region, which is below the photodiode structure of the first semiconductor device, includes a trench structure having highly reflective structures and/or properties to maintain an optical power of light waves propagating through the backside transmissive region. An absence of structures within the trench structure lessens a likelihood of interferences which may cause a transmission loss (e.g., a reflection loss, an absorption loss, a scattering loss, and/or a mode mismatch loss) relative to another transmissive region that is adjacent to the photodiode structure.

### BACKGROUND

A photodetector is a semiconductor device that is configured to receive photons of incident light and convert the photons to an electrical signal. The electrical signal may include a current (referred to as a photocurrent) and/or a voltage, among other examples. The photons generate electron/hole pairs in an absorption region of the photodetector. The electrons and holes are separated and collected at opposing doped collection regions. The photodetector, which may correspond to a semiconductor device that includes a photodiode structure, may be included in a photonics device that is used in an optical communication system.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams showing example implementations of backside transmissive regions in a photonics device described herein.

FIGS. 3A-3I are diagrams showing an example series of semiconductor manufacturing operations for fabricating a semiconductor device including a photodiode structure described herein.

FIGS. 4A-4E are diagrams showing an example series of semiconductor manufacturing operations for fabricating a portion of a photonics device including a backside transmissive region described herein.

FIGS. 5A-5E are diagrams showing an example series of semiconductor manufacturing operations for fabricating a portion of a photonics device including a backside transmissive region described herein.

FIG. 6 is a diagram of example components of a device described herein.

FIG. 7 is a flowchart of an example process associated with fabricating a photonics device including a backside transmissive region described herein.

FIG. 8 is a flowchart associated with operation of a photonics device including a backside transmissive region described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a design of a photonics device includes a transmissive region (e.g., a region transmissive to light waves) that is adjacent to a photodiode structure. Structures included in the transmissive region may interfere with light waves that are received into a semiconductor device including the photodiode structure and propagate laterally through the transmissive region to the photodiode structure. Interferences by the structures may lead to transmission losses of the light waves (e.g., a loss of optical power in decibels (dB) due to one or more of a reflection loss, an absorption loss, a scattering loss, and/or a mode mismatch loss) and reduce a performance of the photonics device (e.g., reduce an effectiveness and/or a sensitivity of the photodiode structure, among other examples). In addition, the design of the photonics device with the transmissive region that is adjacent to the photodiode structure may consume a planar area that causes a size of a system using the photonics device to increase, thereby increasing an overall cost of the module.

Some implementations described herein provide a semiconductor device including a photonics device having a backside transmissive region and methods of manufacturing. The semiconductor device includes a first semiconductor device stacked over a second semiconductor device, where the first semiconductor device includes a photodiode structure and the second semiconductor device includes the backside transmissive region. The backside transmissive region, which is below the photodiode structure of the first semiconductor device, includes a trench structure. An absence of structures within the trench structure lessens a likelihood of interferences which may cause a transmission loss (e.g., a reflection loss, an absorption loss, a scattering loss, and/or a mode mismatch loss) relative to another transmissive region that is adjacent to the photodiode structure. In some implementations, the trench structure includes an optical structure including a metal layer and/or a reflective coating to maintain an optical power of light waves propagating through the transmissive region. Additionally, or alternatively and in some implementations, the semiconductor device includes a micro-lens structure between the trench structure and the photodiode structure. The reflective and focusing properties of the optical structure and/or the micro-lens structure minimize transmissive losses of light propagating through the semiconductor device to the photodiode structure.

In this way, a performance of the photonics device is increased, which may enable the photonics device to achieve greater performance relative to another photonics device not including the backside transmissive region including the trench structure and/or the micro-lens structure. By increasing the yield of the photonics device, the likelihood that the photonics device may be binned to a higher performance category and/or to a more premium product category may be increased.

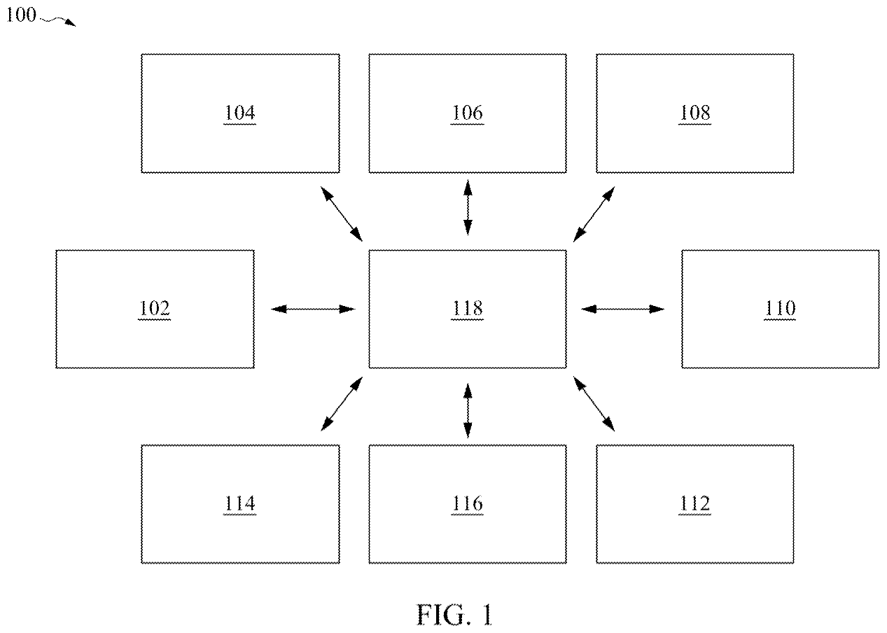

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding/debonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding/debonding tool 116 is a semiconductor processing tool that is capable of joining two or more wafers (or two or more semiconductor substrates, or two or more semiconductor devices) together. For example, the bonding/debonding tool 116 may include a eutectic bonding tool that is capable of forming eutectic bond between two or more wafers together. In these examples, the bonding/debonding tool 116 may heat the two or more wafers to form a eutectic system between the materials of the two or more wafers. As another example, the bonding/debonding tool 116 may include a hybrid bonding tool, a direct bonding tool, and/or another type of bonding tool. In some implementations, the bonding/debonding tool 116 may heat the two or more wafers to separate the two or more wafers.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

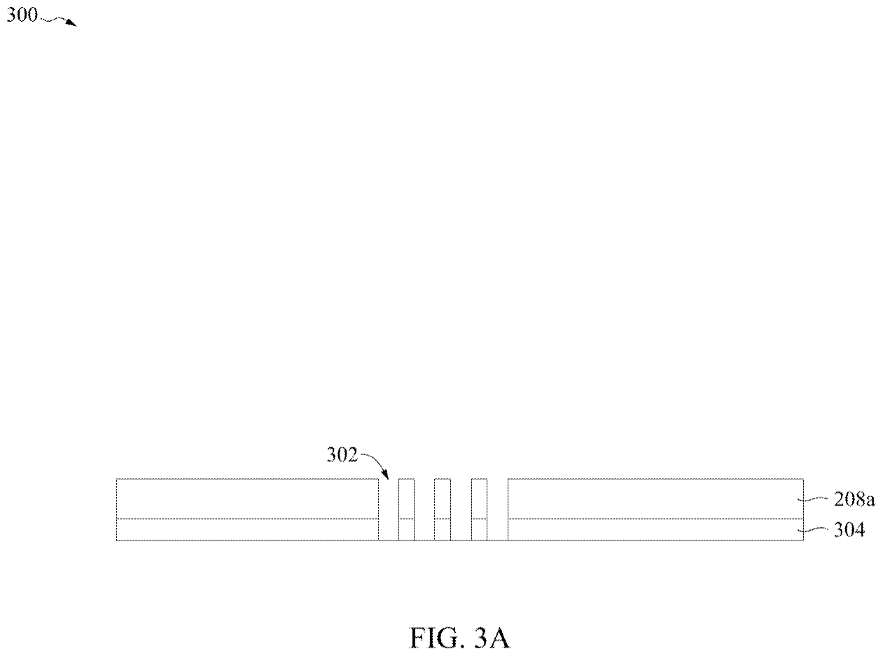

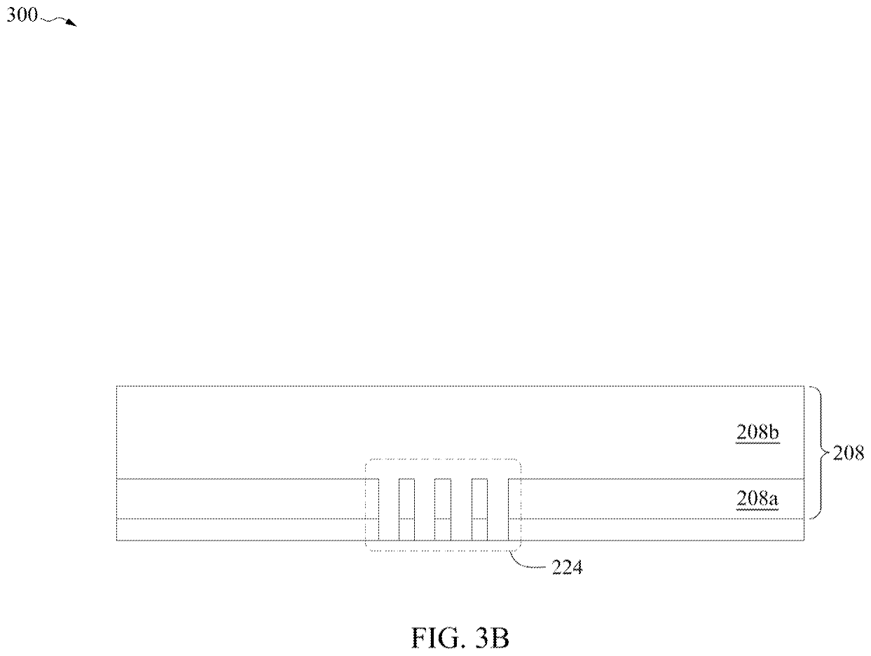

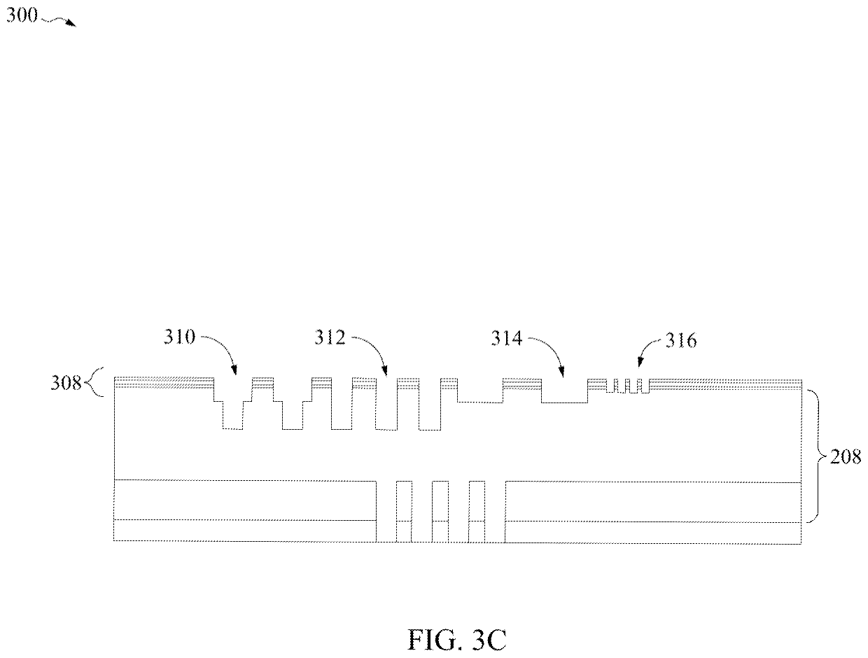

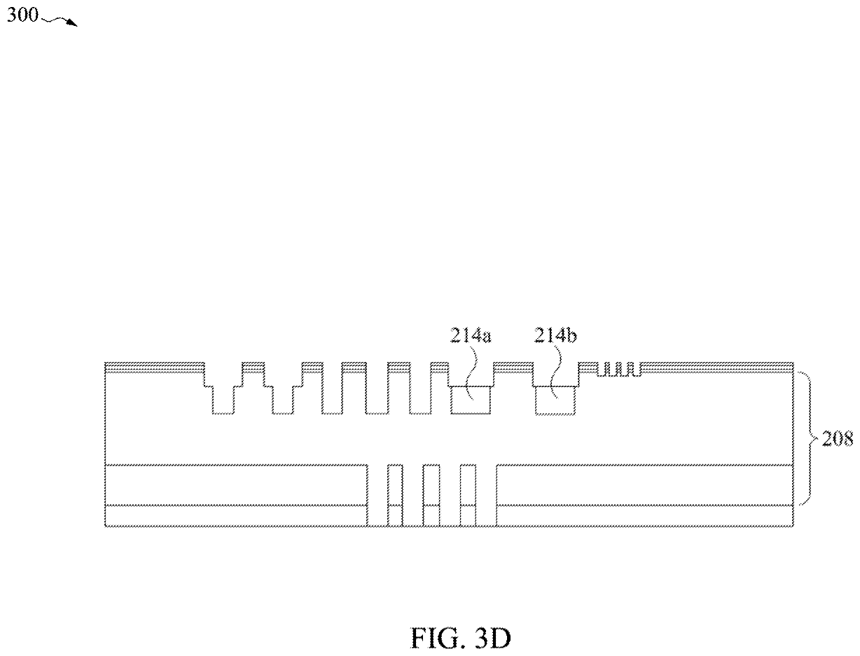

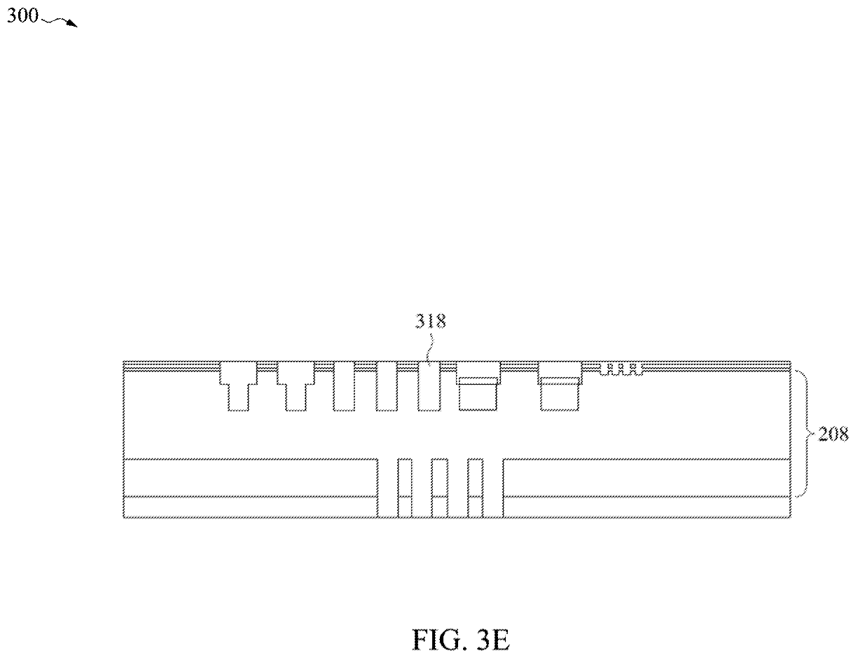

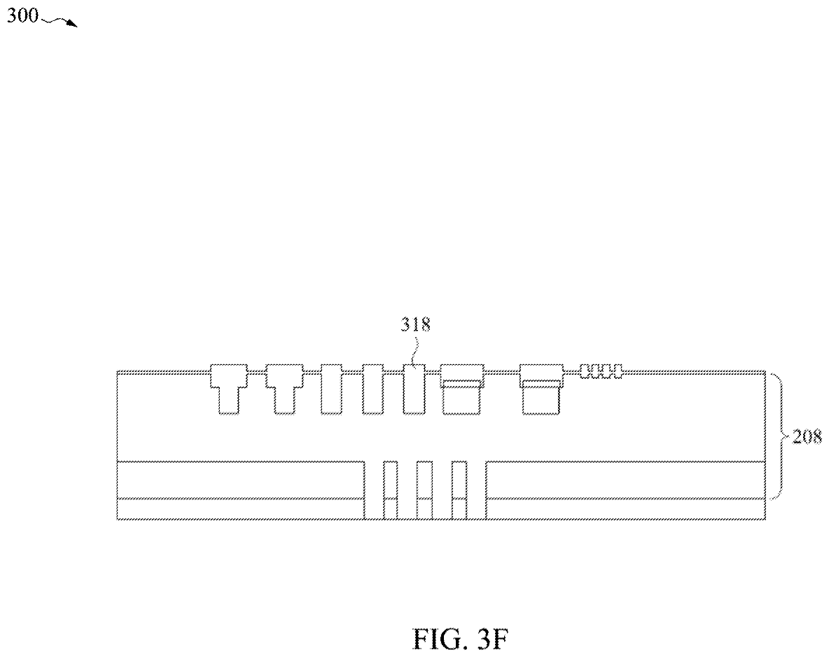

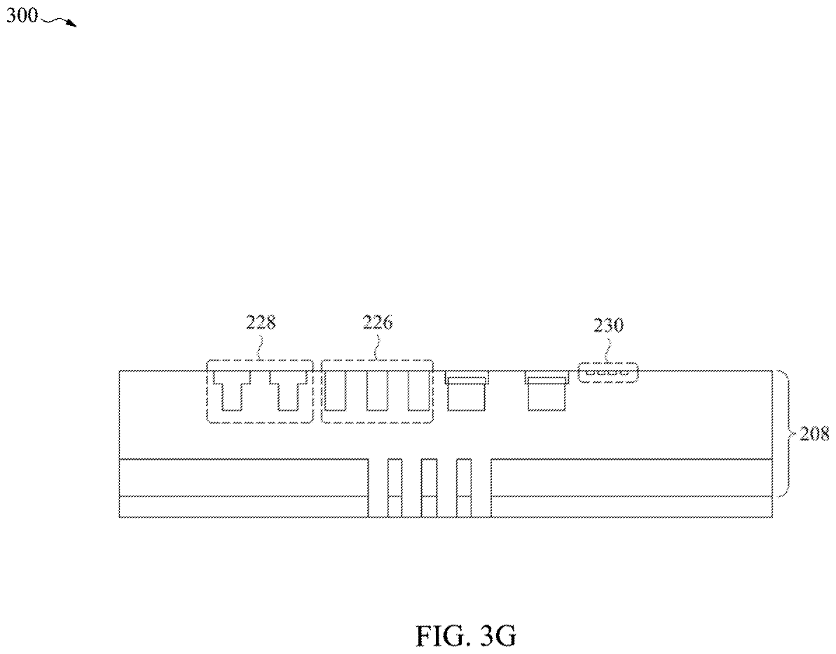

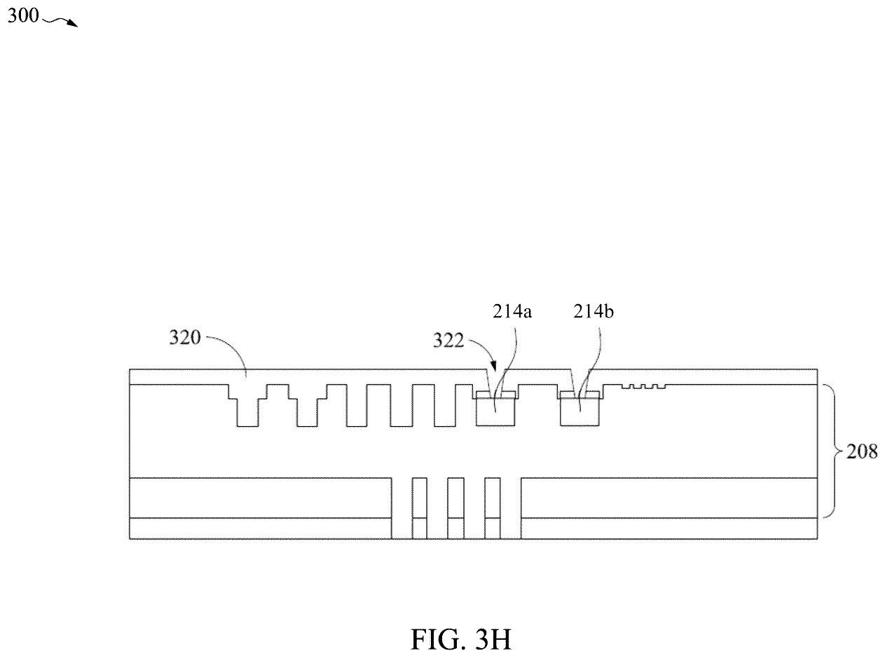

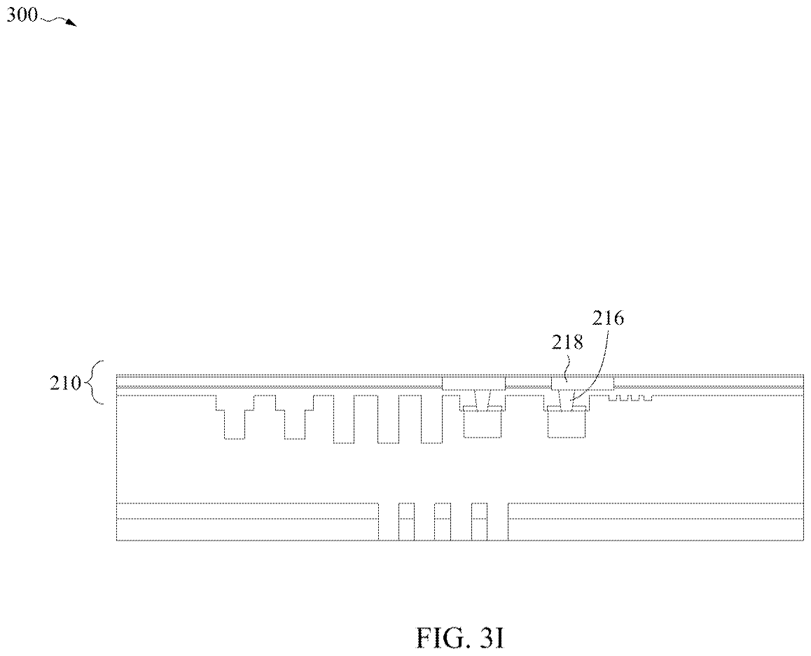

In some implementations, and as described in greater detail in connection with FIGS. 3A-7 and elsewhere herein, one or more of the semiconductor processing tools 102-116 and/or the wafer/die transport tool 118 may be used to perform a series of semiconductor processing operations. The series of semiconductor processing operations includes forming a photodiode structure in a first semiconductor device. The series of semiconductor processing operations includes forming a transmissive region including a vertically-arranged trench structure in a second semiconductor device, where the transmissive region is transmissive to light waves. The series of semiconductor processing operations includes joining the first semiconductor device and the second semiconductor device along a bond line to locate the transmissive region including the vertically-arranged trench structure below the photodiode structure.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may be used to perform one or more functions described as being performed by another set of devices of the example environment 100.

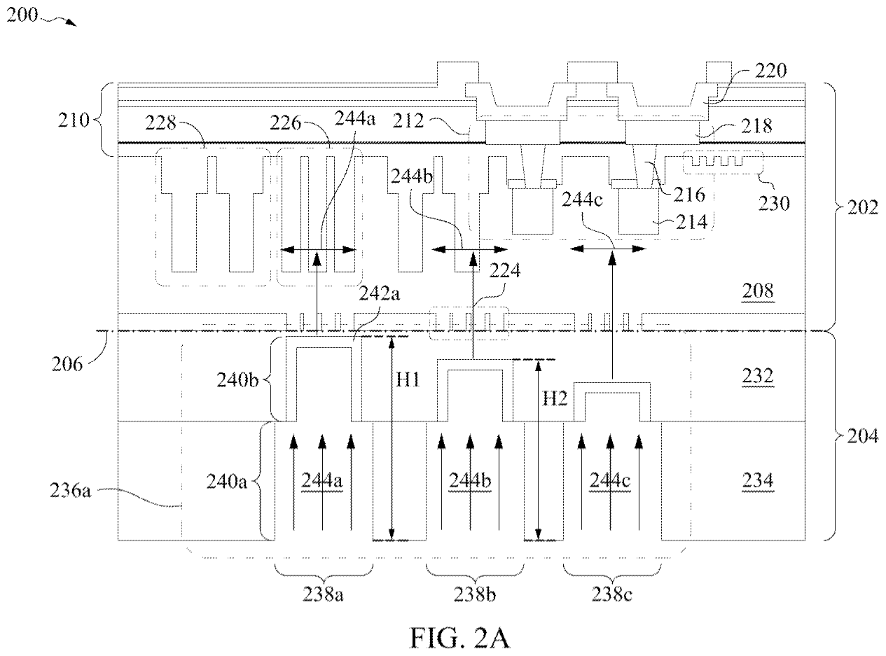

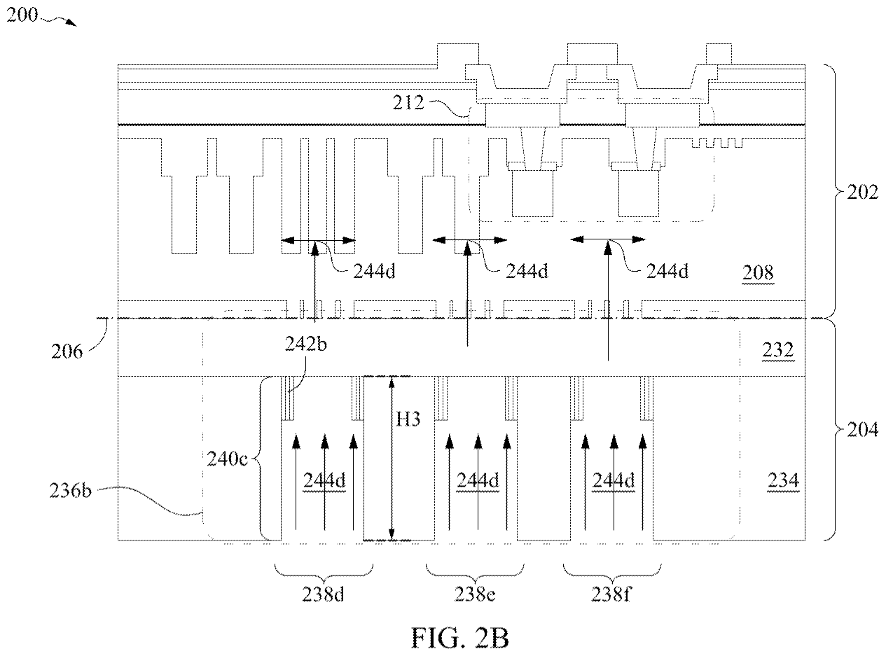

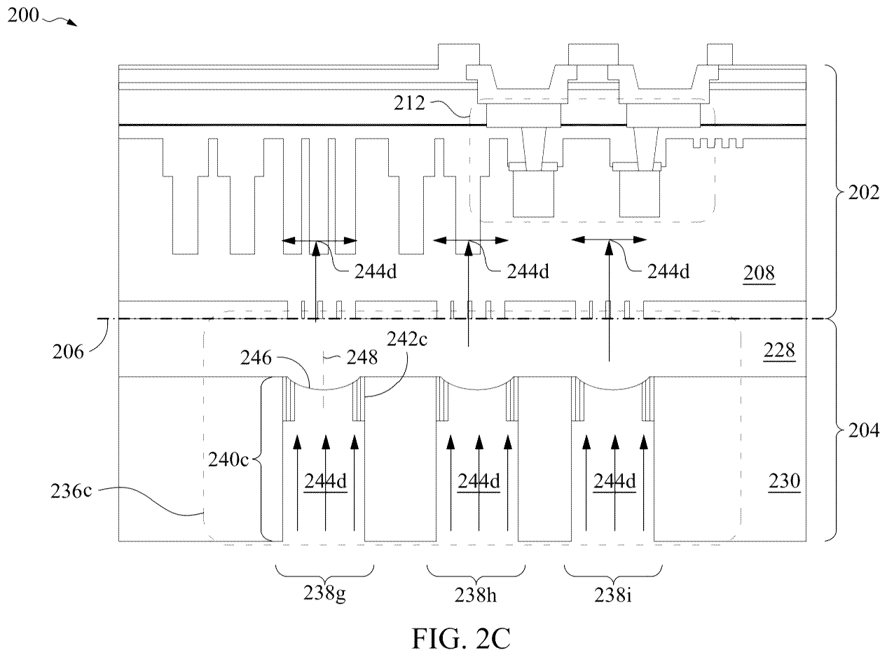

FIGS. 2A-2C are diagrams showing example implementations of backside transmissive regions in a photonics device 200 described herein. In some implementations, the photonics device 200 is included as part of an optical communication system that communicates using laser generated light waves. In each of FIGS. 2A-2C, the photonics device 200 includes a semiconductor device 202 (e.g., an upper semiconductor device) joined with a semiconductor device 204 (e.g., a lower semiconductor device) along a bond line 206 (e.g., a region that may include metal bond pads that are joined through a eutectic bond, among other examples).

As shown in FIG. 2A, the semiconductor device 202 includes a substrate layer 208 (a layer of a silicon (Si) material or another suitable semiconductor material, among other examples), a layer stack 210 (e.g., a stack of layers which may include a combination of dielectric layers, conductive layers, and/or etch stop layers (ESLs)), and a photodiode structure 212. The photodiode structure 212 may include a combination of doped regions 214 (e.g., n-type doped regions and/or p-type doped regions) that form a p-n junction as part of the photodiode structure 212.

In some implementations, and as shown in FIG. 2A, the photodiode structure 212 includes connection structures 216 (e.g., vertical interconnect access (via) structures) connected with metal pads 218. The connection structures 216 and/or the metal pads 218 may include an electrically conductive metal material, such as tungsten material (W), an aluminum (Al) material, or a copper material (Cu), among other examples. Further, and as shown in FIG. 2A, under bump metallurgy (UBM) pads 220 may be connected to the metal pads 218 to provide a path for signals from the photodiode structure 212 to a solder bump or other type of structure for external connectivity.

The semiconductor device 202 may include additional structures for transmission, reflection, and/or redirection of light waves within the semiconductor device 202. For example, and as shown in FIG. 2A, the semiconductor device 202 may include strip waveguide structures 224 and 226, waveguide transition structures 228, and/or distributed Bragg reflector structures 230. The strip waveguide structures 224 and 226, the waveguide transition structures 228, and/or the distributed Bragg reflector structures 230 may each include a respective arrangement and/or combination of materials that are transmissive to light (a silicon material (Si), a silicon dioxide material (SiO₂), or a gallium arsenide material (GaAs), among other examples) and/or materials that are reflective to light (e.g., an aluminum material (Al), a chromium material (Cr), and/or a nickel material (Ni), among other examples).

As further shown in FIG. 2A, the semiconductor device 204 includes a substrate layer 232 (e.g., a layer of a silicon material). The semiconductor device 204 further includes a dielectric layer 234 (e.g., a layer of an oxide material such as a silicon dioxide material (SiO₂) or an aluminum oxide material (Al₂O₃), among other examples) that is below the substrate layer 232.

In some implementations, and as shown in FIG. 2A, the semiconductor device 204 includes a transmissive region 236a (e.g., a backside transmissive region). The transmissive region 236a includes trench structures 238a-238c that are each arranged vertically along a direction that is approximately orthogonal to the bond line 206. Each of the trench structures 238a-238c includes a segment 240a that penetrates through the dielectric layer 234 and a segment 240b that penetrates partially into the substrate layer 232. Furthermore, each of the trench structures 238a-238c may include a gas that is transmissive to light waves (e.g., air).

In some implementations, and as shown in FIG. 2A, an optical structure 242a may be on sidewalls and/or interior surfaces of the segment 240b. The optical structure 242a as shown in FIG. 2A may correspond an Echelle grating structure (e.g., a structure for diffracting light waves). Alternatively, the optical structure 242a may correspond to a distributed Bragg reflector (DBR) structure or a metal reflector structure. In some implementations, a metal patterning of the optical structure 242a includes one or more of an aluminum material (Al), an aluminum copper material (AlCu), an aluminum silicon copper material (AlSiCu), an aluminum silicon material (AlSi), or an aluminum chromium (AlCr), among other examples.

As shown in FIG. 2A, the trench structures 238a-238c are configured to transmit and/or transfer light waves 244a-244c into the semiconductor device 202 for propagation to the photodiode structure 212. In some implementations, the light waves 244a-244c propagate through the trench structures 238a-238c unimpeded. In some implementations, the light waves 244a-244c originate from laser components that are included as part of an optical communication system (laser components using type III/V element laser diodes, among other examples). In some implementations, the light waves 244a-244c each include electromagnetic waves of respective, different wavelengths.

In some implementations, and as shown in FIG. 2A, adjacent trench structures may penetrate into the semiconductor device 204 to different heights. For example, the trench structure 238a may penetrate into the semiconductor device 204 to a height H1, and the trench structure 238b (e.g., an adjacent trench structure) may penetrate into the semiconductor device 204 to a height H2, where the height H2 is lesser relative to the height H1.

In some implementations, a designed or selected height of a trench structure is used to filter and/or refract light and transmit electromagnetic waves of the particular wavelength (in other words, the light waves 244a-244c may include electromagnetic waves of different wavelengths). For example, the light waves 244a transmitted through the trench structure 238a may include electromagnetic waves having a wavelength of approximately 850 nanometers, the light waves 244b transmitted through the trench structure 238b may include electromagnetic waves having a wavelength of approximately 1300 nanometers, and the light waves 244c transmitted through the trench structure 238c may include electromagnetic waves having a wavelength of approximately 1500 nanometers, among other examples. However, different combinations of wavelengths are within the scope of the present disclosure.

As shown in the example implementation of FIG. 2B, the semiconductor device 204 includes the transmissive region 236b. In contrast to the transmissive region 236a described in connection with FIG. 2A, the transmissive region 236b includes trench structures 238d-238f, each of which includes a segment 240c (e.g., a single segment) that penetrates through the dielectric layer 234 (e.g., each of the trench structures 238d-238f excludes a segment that penetrate into the substrate layer 232). Furthermore, each of the trench structures 238d-238f may include a gas that is transmissive to light waves (e.g., air).

In some implementations, and as shown in FIG. 2B, the optical structure 242b may be on sidewalls and/or interior surfaces of the segment 240c. The optical structure 242b as shown in FIG. 2B may correspond to a reflective coating that includes one or more of a silicon dioxide material (SiO₂), a titanium dioxide material (TiO₂), an aluminum arsenide material (AlAs), a gallium arsenide material (GaAs), an aluminum nitride material (AlN), or a gallium nitride material (GaN), among other examples.

Each of the trench structures 238d-238f may penetrate into the semiconductor device 204 to a same approximate height H3. Additionally, each of the trench structures 238d-238f may be configured to transmit and/or transfer light waves 244d into the semiconductor device 202 for propagation to the photodiode structure 212. In some implementations, the light waves 244d propagate through the trench structures 238d-238f unimpeded. In some implementations, the light waves 244d originate from laser components that are included as part of an optical communication system (laser components using type III/V element laser diodes, among other examples). In some implementations, the light waves 244d include electromagnetic waves of similar, approximate wavelengths. In some implementations, the light waves 244d may include electromagnetic waves of different wavelengths.

As shown in the example implementation of FIG. 2C, the semiconductor device 204 includes the transmissive region 236c. In contrast to the transmissive region 236a described in connection with FIG. 2A and the transmissive region 236b described in connection with FIG. 2B, the transmissive region 236c includes trench structures 238g-238i, each of which includes a micro-lens structure 246 that is aligned with an approximate central axis 248 of the segment 240c. The micro-lens structure 246 may be located near an end of the segment 240c that is closest to the bond line 206. Further, and in some implementations and as shown in FIG. 2C, the micro-lens structure 246 has a convex shape.

In some implementations, and as shown in FIG. 2C, the optical structure 242c may be on sidewalls and/or interior surfaces of the segment 240c and near the micro-lens structure 246. The optical structure 242c as shown in FIG. 2C may correspond to a reflective coating that includes one or more of a silicon dioxide material (SiO₂), a titanium dioxide material (TiO₂), an aluminum arsenide material (AlAs), a gallium arsenide material (GaAs), an aluminum nitride material (AlN), or a gallium nitride material (GaN), among other examples.

Each of the trench structures 238g-238i may be configured to transmit and/or transfer the light waves 244d into the semiconductor device 202 for propagation to the photodiode structure 212. Furthermore, each of the trench structures 238d-238f may include a gas that is transmissive to light waves (e.g., air).

In some implementations, the light waves 244d propagate through the trench structures 238d-238f unimpeded. In some implementations, the light waves 244d originate from laser components that are included as part of an optical communication system (laser components using type III/V element laser diodes, among other examples). In some implementations, the light waves 244d include electromagnetic waves of similar, approximate wavelengths. In some implementations, the light waves 244d may include electromagnetic waves of different wavelengths. In some implementations, the micro-lens structure 246 focuses and/or redirects the light waves 244d during entry into the semiconductor device 202.

As described in connection with FIGS. 2A-2C and elsewhere herein, a device (e.g., the photonics device 200) includes a first semiconductor device (e.g., the semiconductor device 202) including a photodiode structure (e.g., the photodiode structure 212). The device includes a second semiconductor device (e.g., the semiconductor device 204) below the first semiconductor device, joined with the first semiconductor device along a bond line (e.g., the bond line 206), and including a trench structure (e.g., the trench structure 238), where the trench structure is arranged in a direction that is approximately orthogonal to the bond line, and where the trench structure is configured to transmit light waves (e.g., the light waves 244a, 244b, 244c, or 244d) into the first semiconductor device for propagation to the photodiode structure.

Additionally, or alternatively and as described in connection with FIGS. 2A-2C and elsewhere herein, a device (e.g., the photonics device 200) may perform a series of operations. The series of operations includes receiving light (e.g., the light waves 244) through a vertically-arranged trench structure (e.g., the trench structure 238) in a lower semiconductor device (e.g., the semiconductor device 204). The method includes transferring the light to a photodiode structure (e.g., the photodiode structure 212) in an upper semiconductor device (e.g., the semiconductor device 202) that is joined with the lower semiconductor device.

In this way, a performance of the photonics device 200 is increased, which may enable the photonics device 200 to achieve greater performance (e.g., an increased effectiveness and/or sensitivity of the photodiode structure 212) relative to another photonics device not including such a trench structure. By increasing the yield of the photonics device 200, a likelihood that the photonics device 200 may be binned to a higher performance category and/or to a more premium product category may be increased.

The number and arrangement of devices shown in FIGS. 2A-2C are provided as one or more examples. In practice, there may be additional devices, fewer devices, different devices, or differently arranged devices than those shown in FIG. 2A-2C. For example, the backside transmissive region 236 described connection with FIGS. 2A-2C may include different quantities of the vertically-arranged trench structure 238 (e.g., 1, 2, 3, 4, etc.). Furthermore, two or more devices shown in FIGS. 2A-2C may be implemented within a single device, or a single device shown in FIGS. 2A-2C may be implemented as multiple, distributed devices.

As indicated above, the example implementations of FIGS. 2A-2C are provided as examples. Other examples may differ from what is described with regard to FIGS. 2A-2C.

FIGS. 3A-3I are diagrams showing an example series of semiconductor manufacturing operations 300 for fabricating a semiconductor device (e.g., the semiconductor device 202) including a photodiode structure (e.g., the photodiode structure 212) described herein.

As shown in FIG. 3A, cavities 302 are formed through the substrate layer 208a (e.g., a first portion of the substrate layer 208) and into a polysilicon layer 304 below on which the substrate layer 208a may be formed. In some implementations, a pattern in a photoresist layer is used to etch the substrate layer 208a and/or the polysilicon layer 304 to form the cavities 302. In these implementations, the deposition tool 102 may be used to form the photoresist layer on the substrate layer 208a. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the substrate layer 208a and/or the polysilicon layer 304 to form the cavities 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 208a and/or the polysilicon layer 304 based on a pattern.

As shown in FIG. 3B, the substrate layer 208b (e.g., a second portion of the substrate layer 208) is formed over and/or on the substrate layer 208a. The deposition tool 102 may be used to deposit the 208b in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the substrate layer 208b after the substrate layer 208b is deposited. As shown in FIG. 3B, forming the substrate layer 208b may include joining with the substrate layer 208a to complete the substrate layer 208. Furthermore, forming the substrate layer 208b may form the strip waveguide structures 224 (e.g., fill the cavities 302 described in connection with FIG. 3A to form the strip waveguide structures 224).

As shown in FIG. 3C, a layer stack 308 (e.g., a stack of layers which may include layers such as dielectric layers, conductive layers, polysilicon layers, and/or etch stop layers (ESLs)) is formed on and/or over the substrate layer 208. The deposition tool 102 and/or the plating tool 112 may be used to deposit one or more layers of the layer stack 308 in a CVD operation, a PVD operation, an ALD operation, an electroplating operation, another deposition operation described above in connection with FIG. 1, and/or another suitable deposition operation. In some implementations, the planarization tool 110 may be used to planarize the layer stack 308 after the layer stack is deposited.

Further, and as shown in FIG. 3C, cavities 310, 312, 314, and 316 are formed through the layer stack 308 and into the substrate layer 208. The cavities 310, 312, 314, and 316 may have a combination of profiles and/or depths. In some implementations, a combination and/or series of patterns in photoresist layers are used to etch the substrate layer 208 to form the cavities 310-316. In these implementations, the deposition tool 102 may be used to form the photoresist layers on the layer stack 308. The exposure tool 104 may be used to expose the photoresist layers to a radiation source to create the combination and/or series of patterns in the photoresist layers. The developer tool 106 may be used to develop and remove portions of the photoresist layers to expose the combination and/or series of patterns. The etch tool 108 may be used to etch the layer stack 308 and substrate layer 208 based on the combination and/or series of patterns to form the cavities 310-316 in the layer stack 308 and the substrate layer 208. In some implementations, etching operations performed by the etch tool 108 include a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 208 based on a combination and/or series of patterns.

As shown in FIG. 3D, doped regions 214a and 214b are formed in the substrate layer 208. The doped region 214a may correspond to an n-type doped region, and the doped region 214b may correspond to a p-type doped region. As part of forming the doped regions 214a and 214b, the ion implantation tool 114 may be used to perform an ion implantation operation as described above in connection with FIG. 1, and/or another suitable implantation operation.

As shown in FIG. 3E, a transmissive fill 318 (e.g., a boron phosphosilicate glass material) is formed (e.g., formed in the cavities 310-316). The deposition tool 102 may be used to deposit a layer of the transmissive fill 318 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize layer of the transmissive fill 318 after the layer of the transmissive fill 318 is deposited.

As shown in FIG. 3F, an etch back operation is performed which removes portions of the layer stack 308. In some implementations, a pattern in a photoresist layer is used to etch and/or remove the portions of the layer stack 308. In such implementations, the deposition tool 102 may be used to form the photoresist layer and/or over the transmissive fill 318. The exposure tool 104 may be used to expose the photoresist layer to a radiation source to pattern the photoresist layer. The developer tool 106 may be used to develop and remove portions of the photoresist layer to expose the pattern. The etch tool 108 may be used to remove portions of the layer stack 308, which may include removing the layer stack 308 in its entirety. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 3G, a planarization operation may be performed as part of forming the strip waveguide structures 226, the waveguide transition structures 228, and/or the distributed Bragg reflector structures 230. The planarization tool 110 may be used to perform the planarization operation as described above in connection with FIG. 1, and/or another suitable planarization operation.

As shown in FIG. 3H, an inter-layer dielectric (ILD) layer 320 (e.g., a layer included in the layer stack 210 described in connection with FIG. 2A) may be formed on and/or over the substrate layer 208. The deposition tool 102 may be used to deposit the ILD layer 320 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the ILD layer 320 after the ILD layer 320 is deposited.

As further shown in FIG. 3H, cavities 322 that extend to the doped regions 214a and 214b are formed through the ILD layer 320. In some implementations, a pattern in a photoresist layer is used to etch the ILD layer 320 to form the cavities 322. In these implementations, the deposition tool 102 may be used to form the photoresist layer on the ILD layer 320. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the ILD layer 320 based on the pattern to form the cavities 322 in the ILD layer 320. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 320 based on a pattern.

As shown in FIG. 3I, the connection structures 216 are formed. As part of forming the connection structures, the deposition tool 102 and/or the plating tool 112 may be used to deposit a layer of a conductive material used for the connection structures 216 in a CVD operation, a PVD operation, an ALD operation, an electroplating operation, another deposition operation described above in connection with FIG. 1, and/or another suitable deposition operation. In some implementations, the planarization tool 110 may be used to planarize the layer of the conductive material after the layer of the conductive material is deposited.

Additionally, and as shown in FIG. 3I, additional layers of the layer stack 210 are formed on and/or over the substrate layer 208. The deposition tool 102 may be used to deposit the additional layers in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the layer stack 210 after the layer stack is deposited.

Additionally, and as shown in FIG. 3I, the metal pads 218 are formed within the layer stack 210. The deposition tool 102, the exposure tool 104, the developer tool 106, and/or the etch tool 108 may be used to perform a series of deposition, patterning, and etching operations to form the metal pads 218 within the layer stack 210.

As indicated above, the example series of semiconductor manufacturing operations of FIGS. 3A-3I is provided as an example. Other examples may differ from what is described with regard to FIGS. 3A-3I.

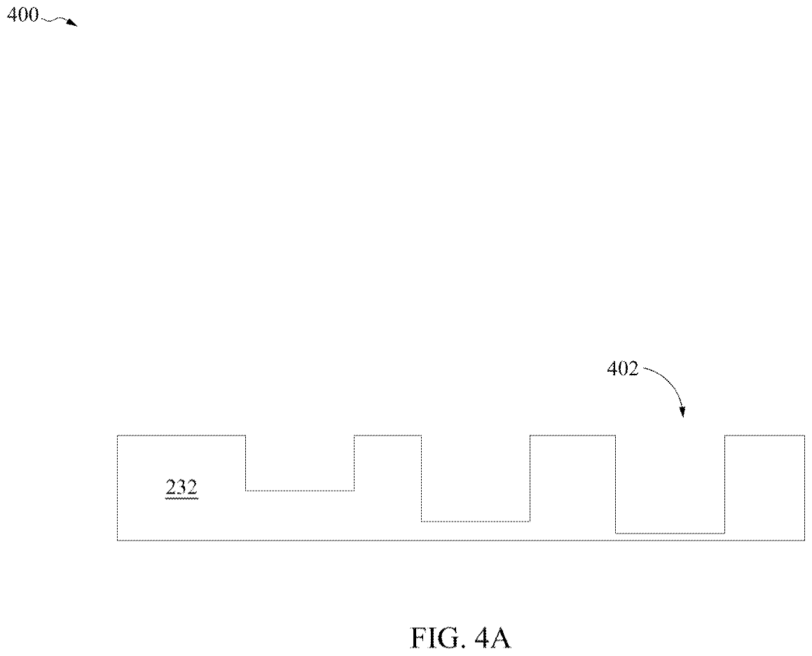

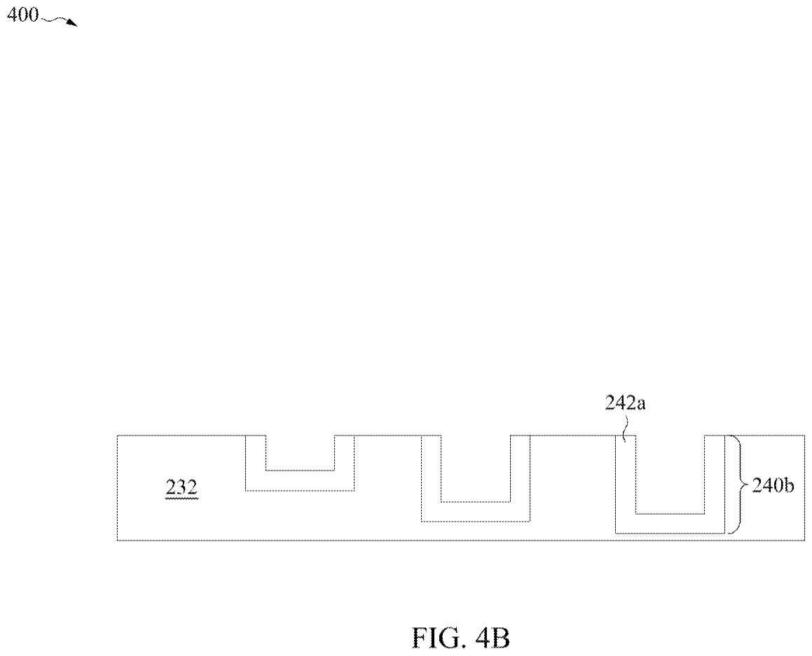

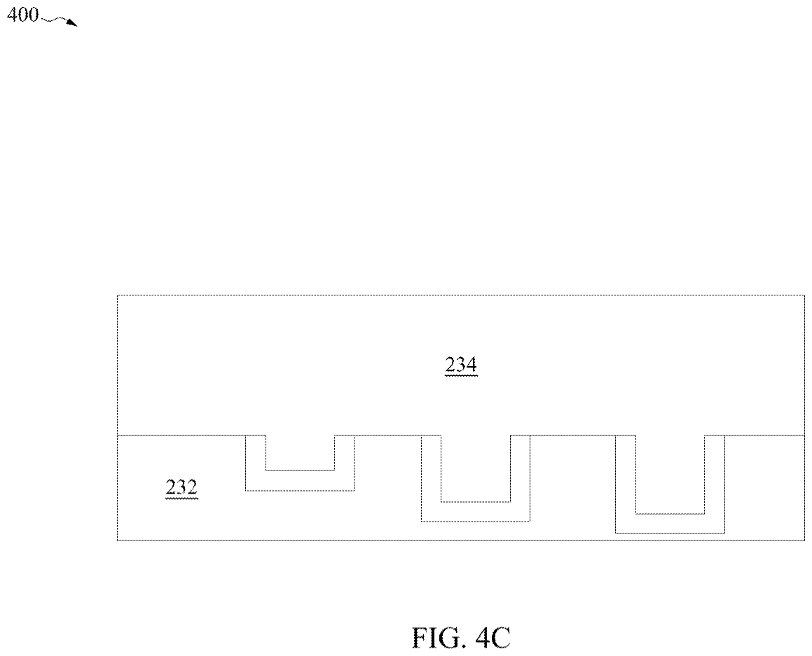

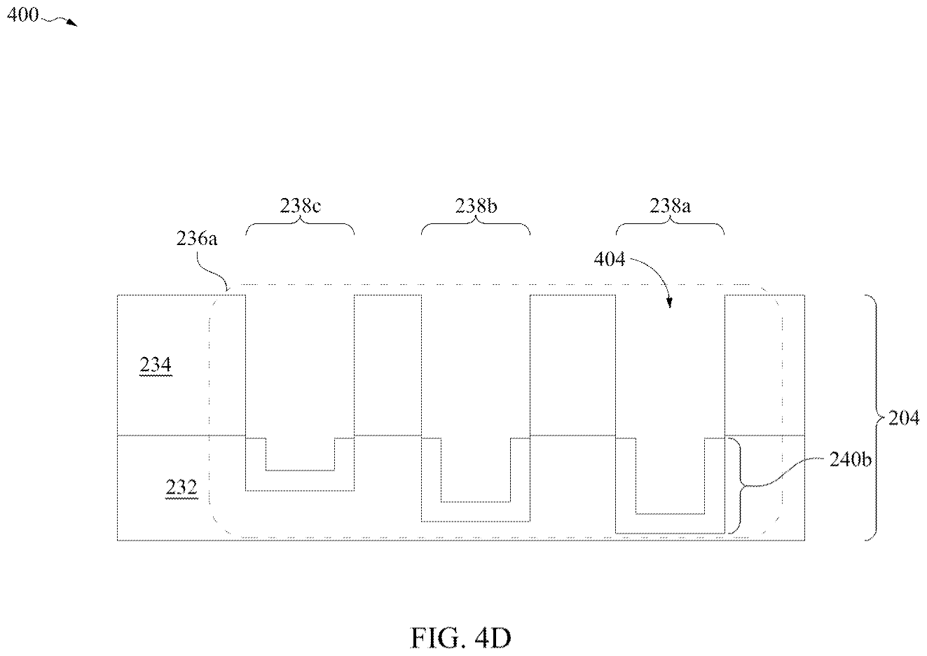

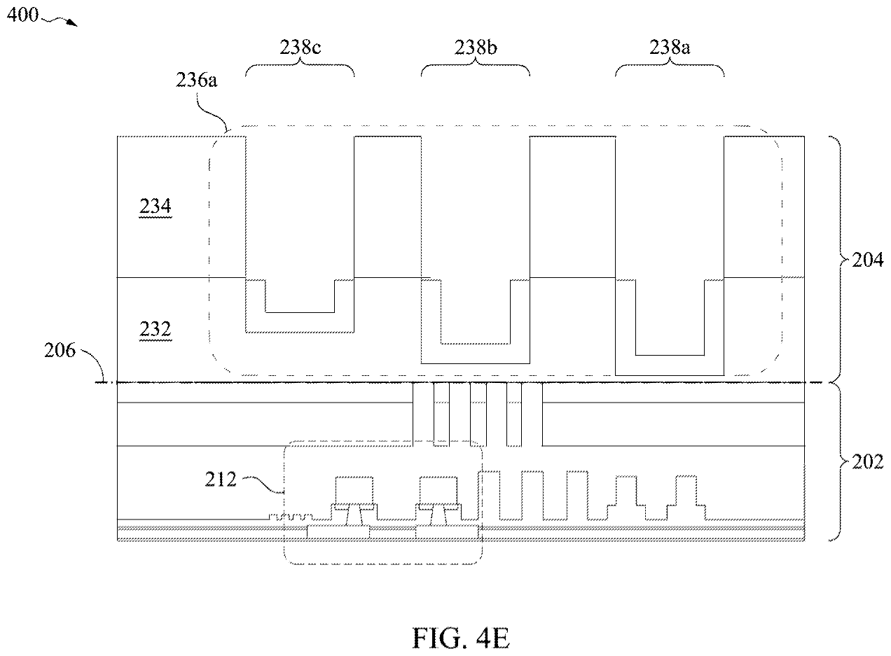

FIGS. 4A-4E are diagrams showing an example series of semiconductor manufacturing operations 400 for fabricating a portion of a photonics device (e.g., the photonics device 200) including a backside transmissive region (e.g., the transmissive region 236a) described herein.

As shown in FIG. 4A, cavities 402 are formed in the substrate layer 232. In some implementations, a pattern in a photoresist layer is used to etch the substrate layer 232 to form the cavities 402. In these implementations, the deposition tool 102 may be used to form the photoresist layer on the substrate layer 232. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the substrate layer 232 based on the pattern to form the cavities 402 in the substrate layer 232. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 232 based on a pattern.

As shown in FIG. 4B, the optical structure 242a is formed as part of forming the segment 240b. The deposition tool 102, the exposure tool 104, the developer tool 106, the etch tool 108, and/or the planarization tool 110 may be used to perform a series of deposition, patterning, etching, and/or planarization operations to form the optical structure 242a. In some implementations, the series of deposition, patterning, etching, and/or planarization operations is dependent on a configuration and/or type of the optical structure 242a (e.g., an Echelle grating pattern, a distributed Bragg reflector structure, or a metal reflector structure). In some implementations, forming the optical structure 242a includes forming the optical structure 242a using one or one or more of an aluminum material (Al), an aluminum copper material (AlCu), an aluminum silicon copper material (AlSiCu), an aluminum silicon material (AlSi), or an aluminum chromium (AlCr), among other examples.

As shown in FIG. 4C, the dielectric layer 234 is formed on and/or over the substrate layer 232. Further, and in some implementations and as shown in FIG. 4C, the dielectric layer fills the segment 240b. The deposition tool 102 may be used to deposit the dielectric layer 234 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 234 after the dielectric layer 234 is deposited.

As shown in FIG. 4D, the transmissive region 236a including the trench structures 238a-238c is formed. As an example, forming the trench structure 238a included in the transmissive region 236a may include the forming a cavity 404 through the dielectric layer 234 and in the segment 240b. In some implementations, a pattern in a photoresist layer is used to etch the dielectric layer 234 to form the cavity 404. In these implementations, the deposition tool 102 may be used to form the photoresist layer on the dielectric layer 234. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 234 based on the pattern to form the cavity 404 in the dielectric layer 234. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 234 based on a pattern. The transmissive region 236a may be included in the semiconductor device 204.

As shown in FIG. 4E, the semiconductor device 204 is joined with the semiconductor device 202 (e.g., the semiconductor device 202 formed using operations described in connection with FIGS. 3A-31). In some implementations, the bonding/debonding tool 116 may be used to forming a eutectic bond between the semiconductor device 202 and the semiconductor device 204 along the bond line 206. The semiconductor devices 202 and 204, as joined, may be a portion of the photonics device 200 described in connection with FIGS. 2A-2C and elsewhere herein.

As indicated above, the example series of semiconductor manufacturing operations of FIGS. 4A-4E is provided as an example. Other examples may differ from what is described with regard to FIGS. 4A-4E.

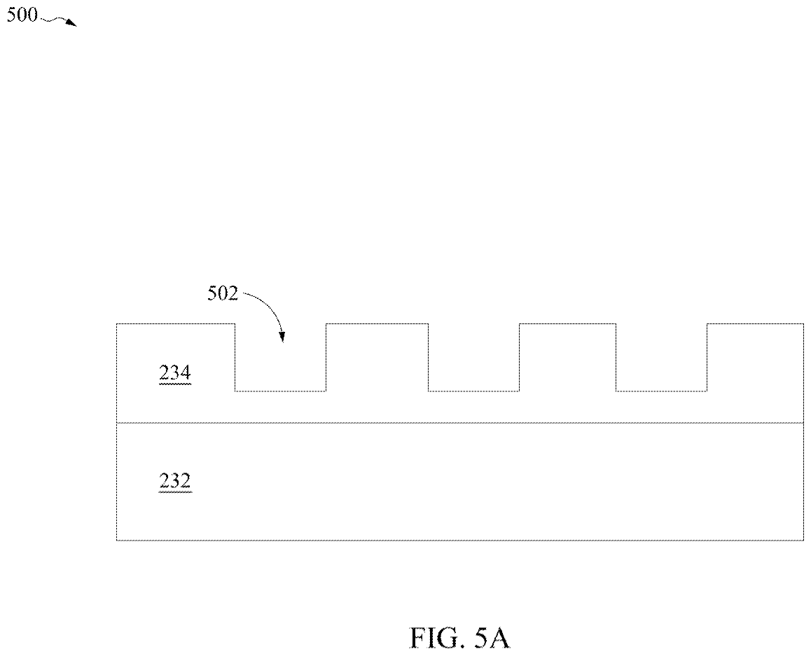

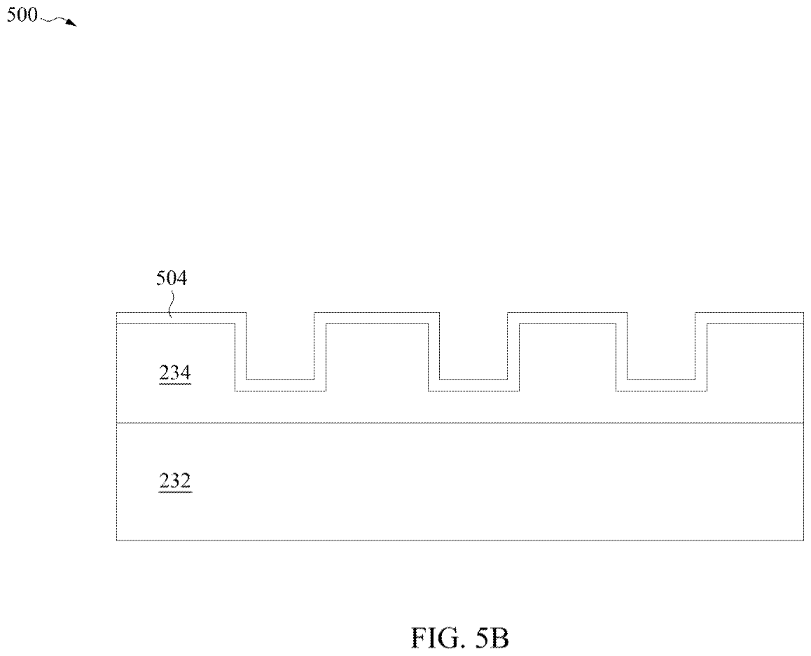

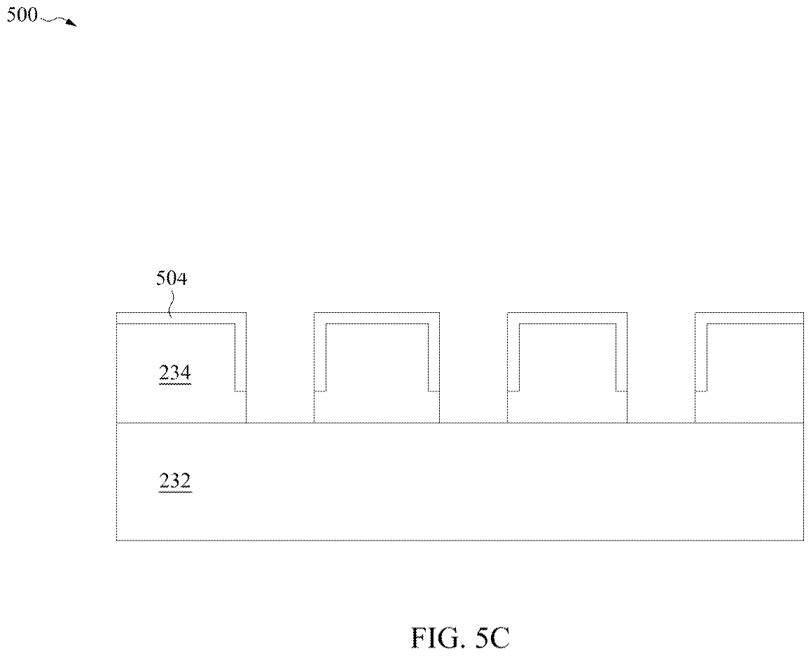

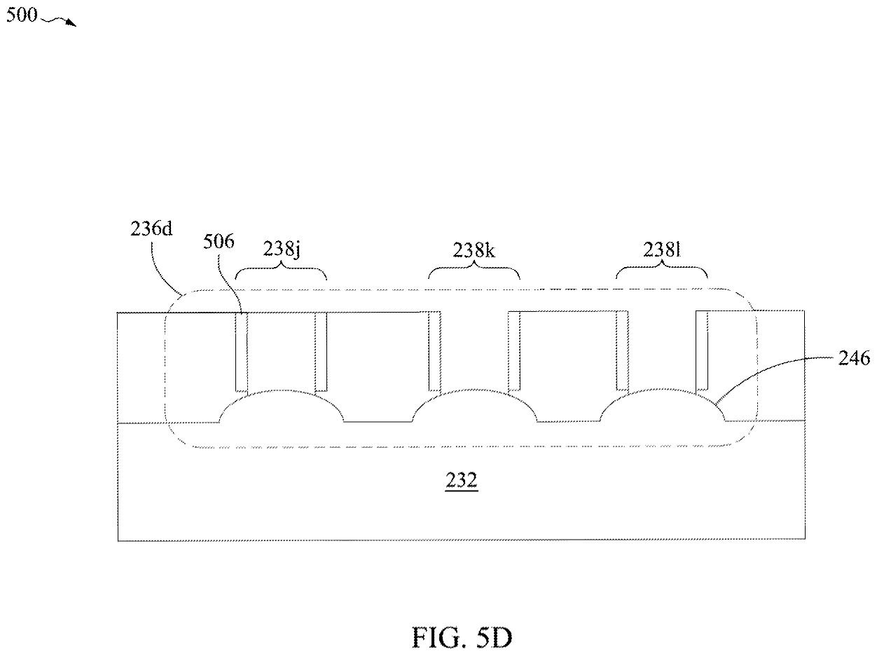

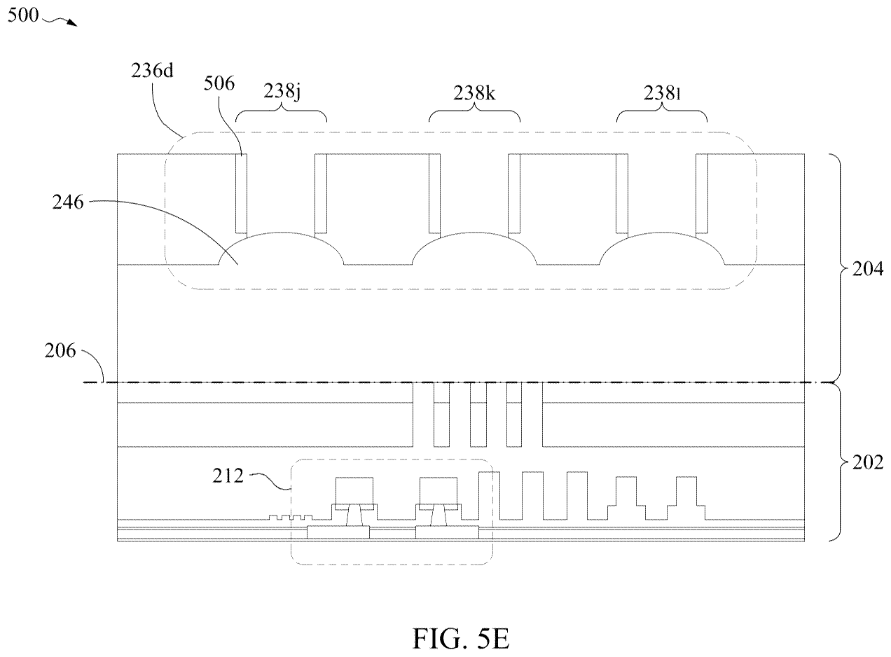

FIGS. 5A-5E are diagrams showing an example series of semiconductor manufacturing operations for fabricating a photonics device including a backside transmissive region described herein.

As shown in FIG. 5A, cavities 502 are formed in the dielectric layer 234. In some implementations, a pattern in a photoresist layer is used to etch the dielectric layer 234 to form the cavities 502. In these implementations, the deposition tool 102 may be used to form the photoresist layer on the dielectric layer 234. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 234 based on the pattern to form the cavities 502 in the dielectric layer 234. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 234 based on a pattern.

As shown in FIG. 5B, conformal layers 504 (e.g., one or more conformal layers of transmissive and/or reflective materials based on a selected type of optical structure such as an Echelle grating pattern, a distributed Bragg reflector structure, or a metal reflector structure) are formed over surfaces of the dielectric layer 234 (e.g., including surfaces of the cavities 502 of FIG. 5A). The deposition tool 102 may be used to deposit the conformal layers in one or more of a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the conformal layers 504 after the conformal layers 504 are deposited.

As shown in FIG. 5C, portions of the conformal layers 504 may be removed to expose a surface of the substrate layer 232. In some implementations, a pattern in a photoresist layer is used to etch the conformal layers 504 to expose the surface of the substrate layer 232. In these implementations, the deposition tool 102 may be used to form the photoresist layer on the conformal layers 504. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the conformal layers 504 based on the pattern to expose the surface of the substrate layer 232. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the conformal layers 504 based on a pattern.

As shown in FIG. 5D, the trench structures 238j-2381 of a transmissive region 236d are formed. As part of forming the trench structures 238j-2381, the planarization tool 110 may be used to remove portions of the conformal layer 504 to form the optical structure 506 (e.g., a segment of an Echelle grating pattern, a distributed Bragg reflector structure, or a metal reflector structure) on surfaces of one or more of the trench structures 238j-2381. Additionally, or alternatively and as part of forming the trench structures 238j-2381, the deposition tool 102 may deposit (e.g., epitaxially grow) the micro-lens structure 246 on exposed surfaces of the substrate layer 232 within one or more of the trench structures 238j-2381.

As shown in FIG. 5E, the semiconductor device 204 that is formed through the operations described in connection with FIGS. 5A-5D is joined with the semiconductor device 202 (e.g., the semiconductor device 202 formed using operations described in connection with FIGS. 3A-31). In some implementations, the bonding/debonding tool 116 may be used to forming a eutectic bond between the semiconductor device 202 and the semiconductor device 204 along the bond line 206. The semiconductor devices 202 and 204, as joined, may be a portion of the photonics device 200 described in connection with FIGS. 2A-2C and elsewhere herein.

As indicated above, the example series of semiconductor manufacturing operations of FIGS. 5A-5E is provided as an example. Other examples may differ from what is described with regard to FIGS. 5A-5E.

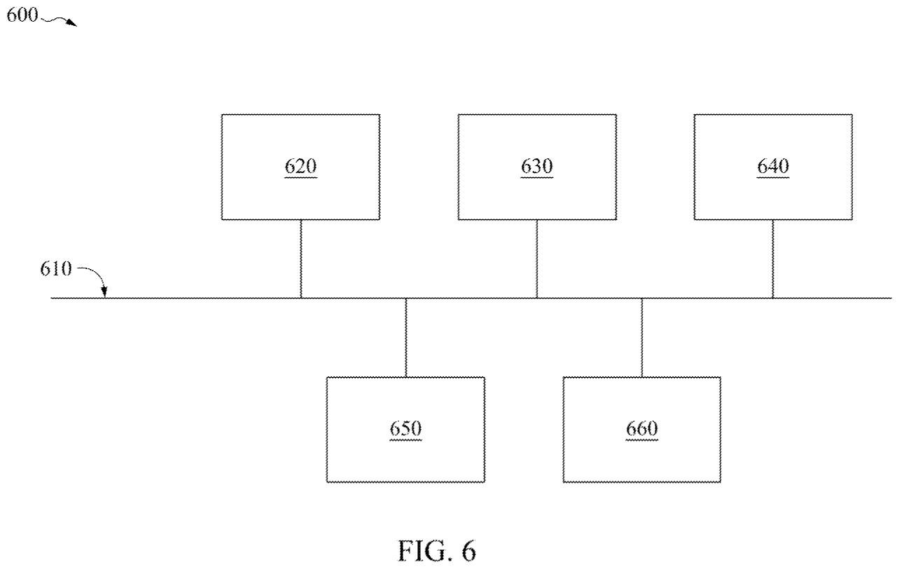

FIG. 6 is a diagram of example components of a device 600 described herein. The device 600 may correspond to one or more of the semiconductor processing tools 102-116 and/or the wafer die transport tool 118. In some implementations, one or more of the semiconductor processing tools 102-116 and/or the wafer die transport tool 118 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

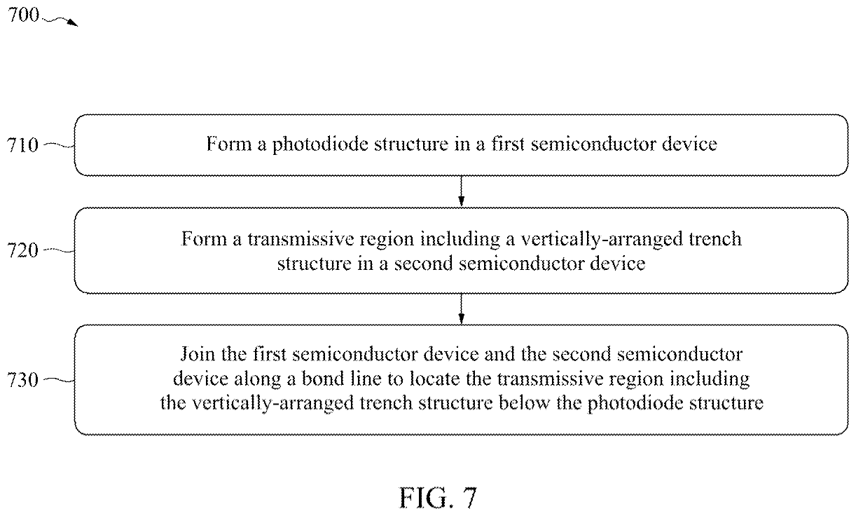

FIG. 7 is a flowchart of an example process 700 associated with fabricating a photonics device including a backside transmissive region described herein. In some implementations, one or more process blocks of FIG. 7 are performed using one or more semiconductor processing tools (e.g., one or more of the semiconductor processing tools 102-116). Additionally, or alternatively, one or more process blocks of FIG. 7 may be performed using one or more components of device 600, such as processor 620, memory 630, input component 640, output component 650, and/or communication component 660.

As shown in FIG. 7, process 700 may include forming a photodiode structure in a first semiconductor device (block 710). For example, one or more of the semiconductor processing tools 102-116 may be used to form a photodiode structure (e.g., the photodiode structure 212) in a first semiconductor device (e.g., the semiconductor device 202), as described herein.

As further shown in FIG. 7, process 700 may include forming a transmissive region including a vertically-arranged trench structure in a second semiconductor device (block 720). For example, one or more of the semiconductor processing tools 102-116 may be used to form a transmissive region (e.g., the transmissive region 236) including a vertically-arranged trench structure (e.g., the trench structure 238) in a second semiconductor device (e.g., the semiconductor device 204), as described herein. In some implementations, the transmissive region is transmissive to light waves (e.g., the light waves 244).

As further shown in FIG. 7, process 700 may include joining the first semiconductor device and the second semiconductor device along a bond line to locate the transmissive region including the vertically-arranged trench structure below the photodiode structure (block 730). For example, one or more of the semiconductor processing tools 102-116 may be used to join the first semiconductor device and the second semiconductor device along a bond line (e.g., the bond line 206) to locate the transmissive region including the vertically-arranged trench structure below the photodiode structure, as described herein.

Process 700 may include additional implementations, such as any single implementation or any combination of implementations described below and/or in connection with one or more other processes described elsewhere herein.

In a first implementation, forming the transmissive region including the vertically-arranged trench structure in the second semiconductor device includes forming a first cavity (e.g., the cavity 402) in a substrate layer (e.g., the substrate layer 232), forming an Echelle grating structure (e.g., the optical structure 242a in the form of an Echelle grating structure) within the first cavity, forming a dielectric layer (e.g., the dielectric layer 234) on the echelle grating structure and over the substrate layer, and forming second cavity (e.g., the cavity 404) through the dielectric layer to the Echelle grating structure.

In a second implementation, alone or in combination with the first implementation, forming the transmissive region including the vertically-arranged trench structure in the second semiconductor device includes forming a cavity (e.g., the cavity 502) in a dielectric layer (e.g., the dielectric layer 234), and forming a reflector structure (e.g., the optical structure 506) within the cavity.

In a third implementation, alone or in combination with one or more of the first and second implementations, forming the transmissive region including the vertically-arranged trench structure further includes forming a micro-lens structure (e.g., the micro-lens structure 246) on a substrate layer (e.g., the substrate layer 232) exposed at a bottom of the cavity.

In a fourth implementation, alone or in combination with one or more of the first through third implementations, forming the reflector structure within the cavity includes forming one or more conformal layers (e.g., the conformal layers 504) of the reflector structure on surfaces of the dielectric layer and the cavity, and removing a portion of the one or more conformal layers from a bottom surface of the cavity.

In a fifth implementation, alone or in combination with one or more of the first through fourth implementations, forming the reflector structure within the cavity includes forming a distributed Bragg reflector structure within the cavity.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

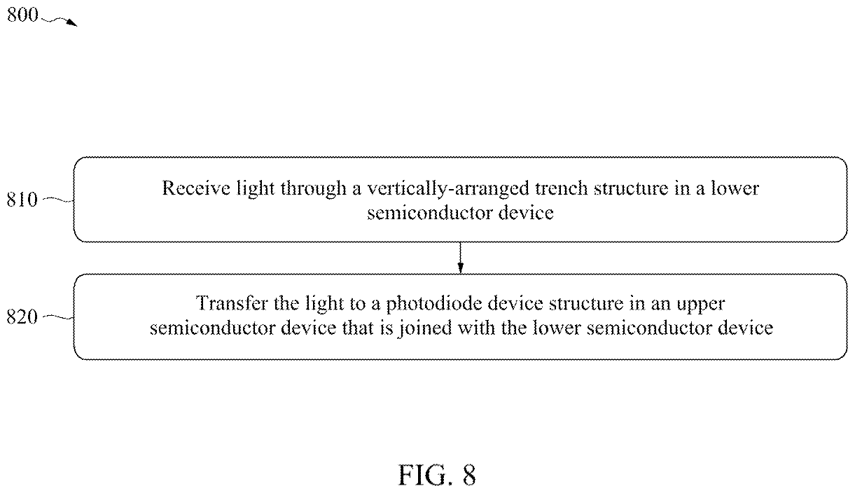

FIG. 8 is a flowchart associated with operation of a photonics device including a backside transmissive region described herein. The photonics device may correspond to the photonics device 200 described in connection with FIGS. 2A-2C and elsewhere herein. Additionally, or alternatively, the backside transmissive region may correspond to the transmissive region 236 describe in connection with FIGS. 2A-2C and elsewhere herein.

As shown in FIG. 8, process 800 may include receiving light through a vertically-arranged trench structure in a lower semiconductor device (block 810). For example, the photonics device 200 may receive light (e.g., the light waves 244) through a vertically-arranged trench structure (e.g., the trench structure 238) in a lower semiconductor device (e.g., the semiconductor device 204), as described above.

As further shown in FIG. 8, process 800 may include transferring the light to a photodiode structure in an upper semiconductor device that is joined with the lower semiconductor device (block 820). For example, the photonics device 200 may transfer the light to a photodiode structure (e.g., the photodiode structure 212) in an upper semiconductor device (e.g., the semiconductor device 202) that is joined with the lower semiconductor device, as described above.

Process 800 may include additional implementations, such as any single implementation or any combination of implementations described below and/or in connection with one or more other processes described elsewhere herein.

In a first implementation, receiving light through a vertically-arranged trench structure in the lower semiconductor device includes receiving light through the vertically-arranged trench structure, where the light is unimpeded by structures within the vertically-arranged trench structure.

In a second implementation, alone or in combination with the first implementation, receiving light through a vertically-arranged trench structure in the lower semiconductor device includes focusing the light using a micro-lens structure (e.g., the micro-lens structure 246) included in the vertically-arranged trench structure.

In a third implementation, alone or in combination with one or more of the first and second implementations, transferring the light to a photodiode structure in the upper semiconductor device that is joined with the lower semiconductor device includes propagating the light through or around a waveguide structure (e.g., the waveguide structure 224) that is included in the upper semiconductor device.

In a fourth implementation, alone or in combination with one or more of the first through third implementations, transferring the light to a photodiode structure in the upper semiconductor device that is joined with the lower semiconductor device includes reflecting the light in the vertically-arranged trench structure using a reflective coating, where the reflective coating includes one or more one or more of a silicon dioxide material (SiO₂), a titanium dioxide material (TiO₂), an aluminum arsenide material (AlAs), a gallium arsenide material (GaAs), an aluminum nitride material (AlN), or a gallium nitride (GaN) material.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

Some implementations described herein provide techniques and apparatuses provide a semiconductor device including a photonics device having a backside transmissive region and methods of manufacturing. The semiconductor device includes a first semiconductor device stacked over a second semiconductor device, where the first semiconductor device includes a photodiode structure and the second semiconductor device includes the backside transmissive region. The backside transmissive region, which is below the photodiode structure of the first semiconductor device, includes a trench structure having highly reflective structures and/or properties to maintain an optical power of light waves propagating through the backside transmissive region. An absence of structures within the trench structure lessens a likelihood of interferences which may cause a transmission loss (e.g., a reflection loss, an absorption loss, a scattering loss, and/or a mode mismatch loss) relative to another transmissive region that is adjacent to the photodiode structure. In some implementations, the trench structure includes one or more reflective properties that maintain an optical power of light waves propagating through the transmissive region.

In this way, a performance of the photonics device is increased, which may enable the photonics device to achieve greater performance relative to another photonics device not having the backside transmissive region including the trench structure. By increasing the yield of the photonics device, the likelihood that the photonics device may be binned to a higher performance category and/or to a more premium product category may be increased.

As described in greater detail above, some implementations described herein provide a device. The device includes a first semiconductor device including a photodiode structure. The device includes a second semiconductor device below the first semiconductor device, joined with the first semiconductor device along a bond line, and including a trench structure, where the trench structure is arranged in a direction that is approximately orthogonal to the bond line, and where the trench structure is configured to transmit light waves into the first semiconductor device for propagation to the photodiode structure.

As described in greater detail above, some implementations described herein provide a method. The method includes forming a photodiode structure in a first semiconductor device. The method includes forming a transmissive region including a vertically-arranged trench structure in a second semiconductor device, where the transmissive region is transmissive to light waves. The method includes joining the first semiconductor device and the second semiconductor device along a bond line to locate the transmissive region including the vertically-arranged trench structure below the photodiode structure.

As described in greater detail above, some implementations described herein provide a method. The method includes receiving light through a vertically-arranged trench structure in a lower semiconductor device. The method includes transferring the light to a photodiode structure in an upper semiconductor device that is joined with the lower semiconductor device.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first semiconductor device comprising:
a photodiode structure; and
a second semiconductor device below the first semiconductor device, joined with the first semiconductor device along a bond line, and comprising:
a backside transmissive region including a trench structure,
wherein the trench structure is arranged in a direction that is approximately orthogonal to the bond line, and
wherein the trench structure is configured to transmit light waves into the first semiconductor device for propagation to the photodiode structure.

2. The device of claim 1, wherein the trench structure comprises:
a segment that penetrates through a dielectric layer of the second semiconductor device and includes a gas that is transmissive to the light waves, and
a distributed Bragg reflector structure on sidewalls of the segment to reflect and redirect light along the direction that is approximately orthogonal to the bond line.

3. The device of claim 2, further comprising:
a micro-lens structure that is aligned with an approximate central axis of the segment and is located near an end of the segment that is closest to the bond line.

4. The device of claim 1, wherein the trench structure comprises:
a first segment that penetrates through a dielectric layer of the second semiconductor device and includes a gas that is transmissive to light waves, and
a second segment in a substrate layer of the second semiconductor device above the dielectric layer,
wherein the second segment is aligned with the first segment.

5. The device of claim 4 wherein interior surfaces of the second segment includes a metal coating to reflect and redirect light along the direction that is approximately orthogonal to the bond line.

6. The device of claim 1, wherein the trench structure is a first trench structure, the direction is a first direction that is approximately orthogonal to the bond line, the light waves are first light waves, and further comprising:
a second trench structure adjacent to the first trench structure,
wherein the second trench structure is arranged in a second direction that is approximately orthogonal to the bond line, and
wherein the second trench structure is configured to transmit second light waves into the first semiconductor device for propagation to the photodiode structure.

7. The device of claim 6, wherein the first trench structure penetrates into the second semiconductor device a first height, and
wherein the second trench structure penetrates into the second semiconductor device a second height that is lesser relative to the first height.

8. The device of claim 6, wherein the first trench structure penetrates into the second semiconductor device a first height, and
wherein the second trench structure penetrates into the second semiconductor device a second height that is a same approximate height as the first height.

9. The device of claim 6, wherein the first light waves correspond to light waves of a first wavelength and the second light waves correspond to light waves of a second wavelength.

10. A method, comprising:
forming a photodiode structure in a first semiconductor device;
forming a transmissive region including a vertically-arranged trench structure in a second semiconductor device,
wherein the transmissive region is transmissive to light waves; and
joining the first semiconductor device and the second semiconductor device along a bond line to locate the transmissive region including the vertically-arranged trench structure below the photodiode structure.

11. The method of claim 10, wherein forming the transmissive region including the vertically-arranged trench structure in the second semiconductor device comprises:
forming a first cavity in a substrate layer;
forming an echelle grating structure within the first cavity;
forming a dielectric layer on the echelle grating structure and over the substrate layer; and
forming second cavity through the dielectric layer to the echelle grating structure.

12. The method of claim 10, wherein forming the transmissive region including the vertically-arranged trench structure in the second semiconductor device comprises:
forming a cavity in a dielectric layer, and
forming a reflector structure within the cavity.

13. The method of claim 12, wherein forming the transmissive region including the vertically-arranged trench structure further comprises:
forming a micro-lens structure on a substrate layer exposed at a bottom of the cavity.

14. The method of claim 12, wherein forming the reflector structure within the cavity comprises:
forming one or more conformal layers of the reflector structure on surfaces of the dielectric layer and the cavity, and
removing a portion of the one or more conformal layers from a bottom surface of the cavity.

15. The method of claim 12, wherein forming the reflector structure within the cavity comprises:
forming a distributed Bragg reflector structure within the cavity.

16. A method, comprising:
receiving light through a vertically-arranged trench structure in a lower semiconductor device; and
transferring the light to a photodiode structure in an upper semiconductor device that is joined with the lower semiconductor device.

17. The method of claim 16, wherein receiving light through a vertically-arranged trench structure in the lower semiconductor device comprises:
receiving light through the vertically-arranged trench structure,
wherein the light is unimpeded by structures within the vertically-arranged trench structure.

18. The method of claim 16, wherein receiving light through a vertically-arranged trench structure in the lower semiconductor device comprises:
focusing the light using a micro-lens structure included in the vertically-arranged trench structure.

19. The method of claim 16, wherein transferring the light to a photodiode structure in the upper semiconductor device that is joined with the lower semiconductor device comprises:
propagating the light through or around a waveguide structure that is included in the upper semiconductor device.

20. The method of claim 16, wherein transferring the light to a photodiode structure in the upper semiconductor device that is joined with the lower semiconductor device comprises reflecting the light in the vertically-arranged trench structure using a reflective coating, wherein the reflective coating includes one or more of:
a silicon dioxide material,
a titanium dioxide material,
an aluminum arsenide material,
a gallium arsenide material,
an aluminum nitride material, or
a gallium nitride material.
